(19) United States
(12) Patent Application Publication
(10) Pub. No.: US 2009/0114434 A1
(43) Pub. Date: May 7, 2009

(54) METHOD OF MANUFACTURING NON-SHRINKAGE CERAMIC SUBSTRATE AND NON-SHRINKAGE CERAMIC SUBSTRATE USING THE SAME

(75) Inventors: Min Ji Ko, Suwon (KR); Jong Myeon Lee, Gwacheon (KR); Eun Tae Park, Yongin (KR)

Correspondence Address: MCDERMOTT WILL & EMERY LLP, 18191 VON KARMAN AVE., SUITE 500, IRVINE, CA, 92612-7108, US

(73) Assignee: SAMSUNG ELECTRO-MECHNICS CO., LTD., Suwon (KR)

(21) Appl. No.: 12/264,883

(22) Filed: Nov. 4, 2008

(30) Foreign Application Priority Data
Nov. 5, 2007 (KR) 10-2007-0112115

(51) Int. Cl. H05K 3/10; H05K 1/00

(52) U.S. Cl. 174/258; 427/97.4

(57) ABSTRACT

There is provided a method of manufacturing a non-shrinkage ceramic substrate, and a non-shrinkage ceramic substrate using the same. A method of manufacturing a non-shrinkage ceramic substrate by firing a ceramic laminate including an internal electrode circuit pattern according to an aspect of the invention may include: laminating at least one constraining ceramic sheet on each of the upper and lower surfaces of the ceramic laminate to form constraining layers; performing a primary firing process on the ceramic laminate having the constraining layers thereon; polishing the surface of the ceramic laminate from which the constraining layers are removed; forming ceramic paste on the polished surface of the ceramic laminate while exposing connection terminals of the internal electrode circuit pattern to the outside environment through openings in the ceramic paste; forming a surface electrode on the surface of the ceramic paste by patterning so that the surface electrode is electrically connected to the connection terminals; and performing a secondary firing process so that the surface electrode adheres to the ceramic paste.

### CROSS-REFERENCE TO RELATED APPLICATIONS

This application claims the priority of Korean Patent Application No. 2007-0112115 filed on Nov. 5, 2007, in the Korean Intellectual Property Office, the disclosure of which is incorporated herein by reference.

### BACKGROUND OF THE INVENTION

1. Field of the Invention

The present invention relates to methods of manufacturing a non-shrinkage ceramic substrate that can increase adhesion between a substrate and a surface electrode, and non-shrinkage ceramic substrates using the same, and more particularly, to a method of manufacturing a non-shrinkage ceramic substrate that can increase adhesion between a substrate and a surface electrode by forming ceramic paste, which is formed of the same material as a ceramic laminate (substrate), on the ceramic laminate, forming a surface electrode on the surface thereof, and co-firing the ceramic paste and the surface electrode, and a non-shrinkage ceramic substrate using the same.

2. Description of the Related Art

Ceramic substrates or multi-layer ceramic substrates have been widely used as a substitution for existing printed circuit boards (PCBs) since they have thermal resistance, wear resistance, and excellent electrical characteristics. The demand thereof is gradually increasing.

Recently, a reduction in size and accuracy of low temperature co-fired ceramic (LTCC) substrates have been required. However, the existing shrinkage method is more likely to cause a problem with the control of the accuracy. Many manufacturers of LTCC substrates use non-shrinkage methods to solve this problem. One example of these non-shrinkage methods may include constrained firing that has been developed so that an LTCC substrate does not shrink along a longitudinal direction and a thickness direction during firing.

FIGS. 1A to 1E are a schematic view illustrating a process of manufacturing a ceramic laminate. A plurality of green sheets 1 are formed on carrier films (not shown) by using general tape casting. Each of the green sheets 1 may be composed of glass-ceramics that contain borosilicate glass of 60% or more and residual alumina.

As shown in FIGS. 1A to 1E, via holes 2 are formed in the green sheet 1 at predetermined positions. Each of the via holes 2 is filled with a conductor to form a connection terminal 3.

An internal electrode 4 is formed on a predetermined green sheet 1 by patterning. A necessary number of green sheets 1 are laminated and compressed to form a ceramic laminate 10 that includes the internal electrode 4.

A process of manufacturing a ceramic substrate according to the general constrained firing process includes laminating constraining layers on the top and bottom of the ceramic substrate, and firing the ceramic substrate including the constraining layers so that the ceramic substrate can shrink only in a thickness direction to thereby reduce the volume of the ceramic substrate. However, a surface electrode is damaged by the constraining layers.

FIGS. 2A to 2F are a view illustrating a process of preventing damage to the surface electrode. Constraining layers 11 are formed on upper and lower surfaces of the laminate 10, which is then fired. Then, the constraining layers 11 are removed, and the surface of the laminate is polished, thereby manufacturing the ceramic substrate.

A post process of forming a surface electrode 14 on the surface of the ceramic substrate and re-firing the surface electrode 14 is also performed.

Even though the post process is performed to prevent damage to the surface electrode, the ceramic sheets are crystallized during the firing process, which causes a poor adhesion between the ceramic substrate and the surface electrode during re-firing.

### SUMMARY OF THE INVENTION

An aspect of the present invention provides a non-shrinkage ceramic substrate that can increase adhesion between ceramic paste (substrate) and a surface electrode during re-firing by forming ceramic paste, formed of the same material as the ceramic substrate, and forming the surface electrode on an upper surface thereof, and a non-shrinkage ceramic substrate using the same.

According to an aspect of the present invention, there is provided a method of manufacturing a non-shrinkage ceramic substrate by firing a ceramic laminate including an internal electrode circuit pattern, the method including: laminating at least one constraining ceramic sheet on each of the upper and lower surfaces of the ceramic laminate to form constraining layers; performing a primary firing process on the ceramic laminate having the constraining layers thereon; polishing the surface of the ceramic laminate from which the constraining layers are removed; forming ceramic paste on the polished surface of the ceramic laminate while exposing connection terminals of the internal electrode circuit pattern to the outside environment through openings in the ceramic paste; forming a surface electrode on the surface of the ceramic paste by patterning so that the surface electrode is electrically connected to the connection terminals; and performing a secondary firing process so that the surface electrode adheres to the ceramic paste.

The ceramic paste may be formed of the same material as the ceramic laminate.

The ceramic paste may be formed by screen printing.

The secondary firing may be co-firing so that the ceramic paste and the ceramic laminate are integrally formed with each other.

According to another aspect of the present invention, there is provided a method of manufacturing a non-shrinkage ceramic substrate by firing a ceramic laminate including an internal electrode circuit pattern, the method including: laminating a dummy ceramic sheet on an upper surface of the ceramic laminate to form a dummy layer; forming at least one constraining ceramic sheet on an upper surface of the dummy layer and a lower surface of the ceramic laminate; performing a primary firing process on the ceramic laminate against which the dummy layer and the constraining layers are compressed; polishing the surface of the ceramic laminate from which the dummy layer and the constraining, layers are removed; forming ceramic paste on the polished surface of the ceramic laminate while exposing connection terminals of the internal electrode circuit pattern to the outside environment through openings in the ceramic paste; forming a surface electrode on the surface of the ceramic paste so that the surface electrode is electrically connected to the connection terminals; and performing a secondary firing process so that the surface electrode adheres to the ceramic paste.

The ceramic paste may be formed of the same material as the ceramic laminate.

The ceramic paste may be formed by screen printing. The secondary firing may be co-firing so that the ceramic paste and the ceramic laminate are integrally formed with each other.

According to still another aspect of the present invention, there is provided a non-shrinkage ceramic substrate including: a ceramic laminate having an internal electrode circuit pattern therein; ceramic paste provided on the polished surface of the ceramic laminate after firing while exposing connection terminals of the internal electrode circuit pattern to the outside environment through openings in the ceramic paste; and a surface electrode provided on the upper surface of the ceramic paste so that the surface electrode is electrically connected to the connection terminals.

The ceramic paste may be provided between the ceramic laminate and the surface electrode, and provided on a surface of the ceramic laminate while exposing the connection terminals to the outside environment through openings in the ceramic paste, so that the surface electrode is electrically connected to the connection terminals of the internal electrode circuit pattern.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A to 1E are a schematic view illustrating a process of manufacturing a ceramic laminate;

FIGS. 2A to 2F are a view illustrating a process of manufacturing a ceramic substrate by using a constrained firing method according to the related art;

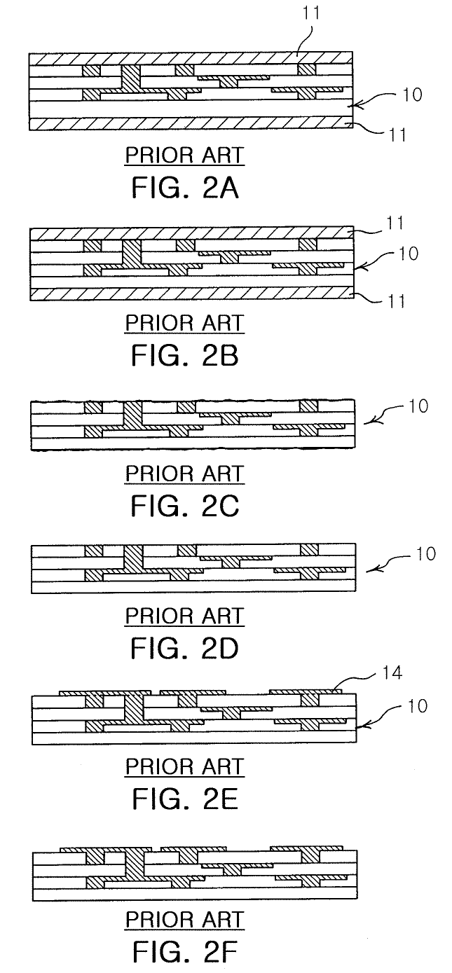

FIGS. 3A to 3G are a schematic view illustrating a process of manufacturing a ceramic substrate according to an exemplary embodiment of the invention; and

FIGS. 4A to 4H are a schematic view illustrating a method of manufacturing a ceramic substrate according to another exemplary embodiment of the invention.

### DETAILED DESCRIPTION OF THE PREFERRED EMBODIMENT

Exemplary embodiments of the present invention will now be described in detail with reference to the accompanying drawings.

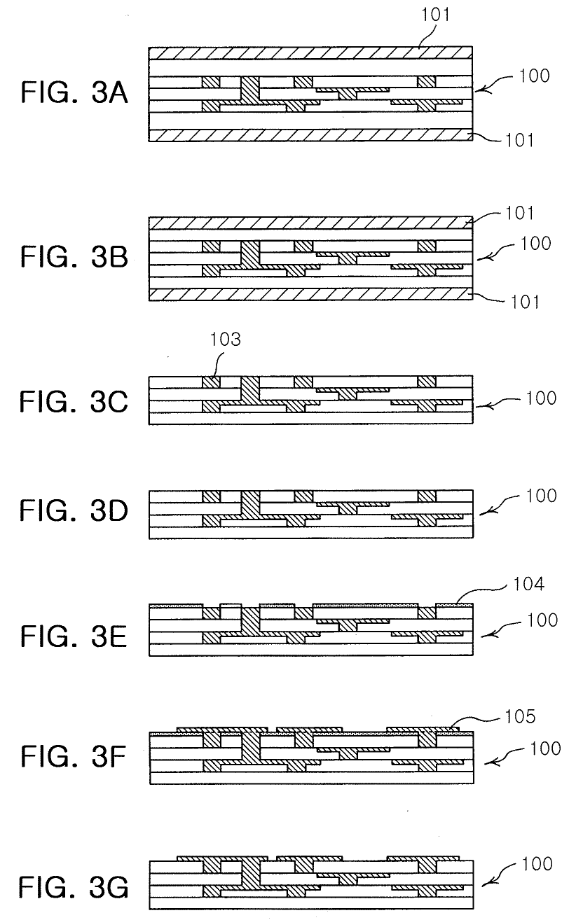

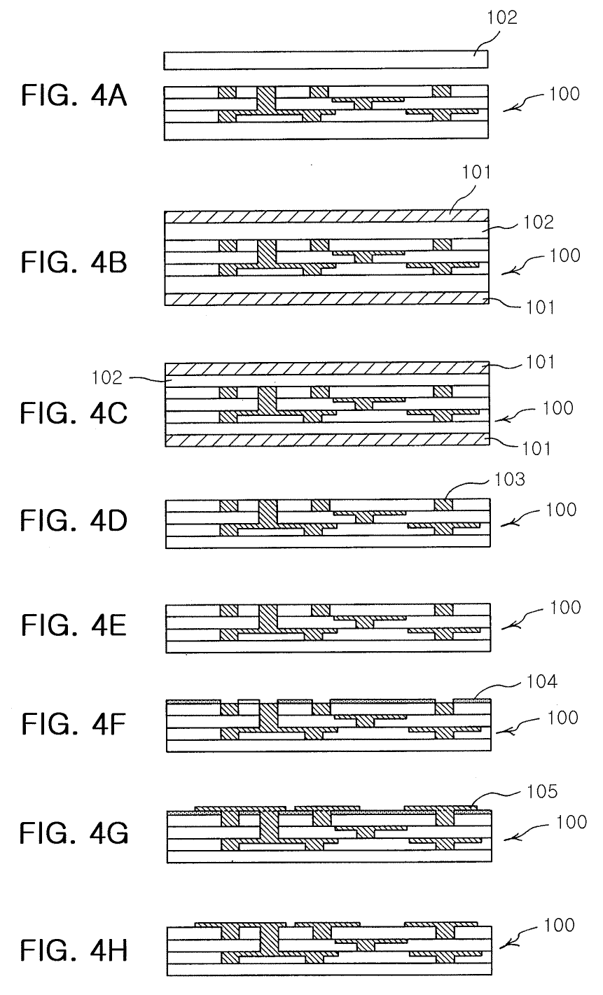

FIGS. 3A to 3G are a schematic view illustrating a process of manufacturing a ceramic substrate according to an exemplary embodiment of the invention. FIGS. 4A to 4H are a schematic view illustrating a process of manufacturing a ceramic substrate according to another exemplary embodiment of the invention.

A ceramic substrate according to an exemplary embodiment of the invention includes a ceramic laminate 100, ceramic paste 104, and a surface electrode 105. An internal electrode circuit pattern is provided in the ceramic laminate 100. The ceramic paste 104 is formed on the polished surface of the laminate after firing while connection terminals of the internal electrode circuit pattern are exposed to the outside environment through openings in the ceramic paste 104. The surface electrode 105 is formed on an upper surface of the ceramic paste 104, such that the surface electrode 105 is electrically connected to the connection terminals.

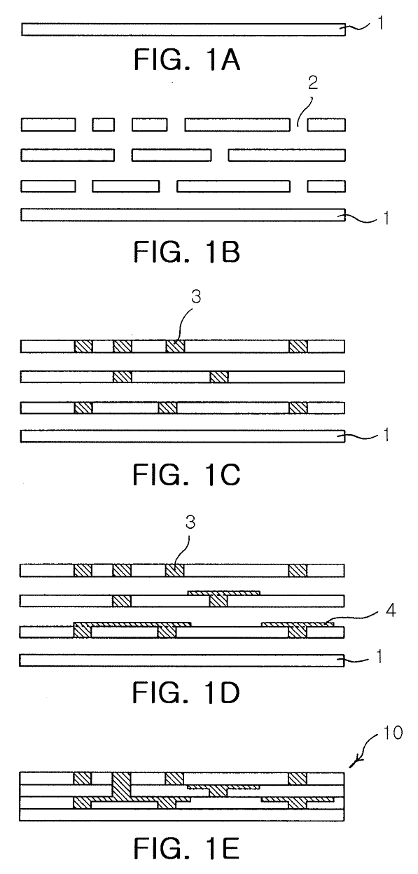

Constraining layers 101 are laminated on upper and lower surfaces of the manufactured ceramic laminate 100, as shown in FIG. 1E. The ceramic laminate 100 including the constraining layers is fired at a predetermined temperature, and the constraining layers 101 are then removed. In this way, the ceramic laminate 100 is manufactured.

Each of the constraining layers 101 is formed of an inorganic material, an organic binder, a plasticizer, and a solvent. Examples of the inorganic material may include alumina, zirconia, and magnesia.

The organic binder, the plasticizer, and the solvent may be the same as those used to form green sheets of the laminate 100.

Preferably, the constraining layers 101 may not be sintered at firing temperature of the laminate 100. In general, the firing temperature is 1000° C. or higher. After the firing process, the constraining layers 101 are removed by using methods, such as ultrasonic cleaning, water jetting, chemical blasting, and sand blasting.

The ceramic paste 104 has the same material as the laminate 100. The ceramic paste 104 is formed by screen printing on the upper surface of the laminate 100 that is smoothed by polishing.

Here, the ceramic paste 104 is printed onto the upper surface of the laminate 100 while connection terminals 103 are exposed to the outside environment through openings in the ceramic paste 104.

The surface electrode 105 is formed on the upper surface of the ceramic paste 104, and is electrically connected to the connection terminals 103.

That is, while the ceramic paste 104 is located between the ceramic laminate 100 and the surface electrode 105, the ceramic paste 104 is not located at the connection terminals 103 that are exposed to the outside environment through the openings in the ceramic laminate 100. Therefore, the surface electrode 105, formed on the upper surface of the ceramic paste 104, is electrically connected to the connection terminals 103 of the internal electrode circuit pattern.

Therefore, when the ceramic paste 104 and the surface electrode 105 are co-fired, the adhesion between the ceramic paste 104 and the surface electrode 105 can be increased.

Hereinafter, the method of manufacturing a ceramic substrate according to one exemplary embodiment of the invention will be described in detail.

As shown in FIG. 3A, the ceramic laminate 100 is subjected to a non-shrinkage process to manufacture a ceramic substrate. At least one constraining ceramic sheet is laminated on each of the upper and lower surfaces of the laminate 100 including the internal electrode to form the constraining layers 101.

The non-shrinkage process is then performed so that the laminate 100 having the constraining layers 101 thereon is fired at a predetermined temperature, and allowed to shrink only in a thickness direction (FIG. 3B).

Then, the constraining layers 101 are removed by using methods, such as ultrasonic cleaning, water jetting, chemical blasting, sand blasting, and wet blasting (FIG. 3C).

The upper surface of the laminate 100 is smoothed by polishing, and the ceramic paste 104, formed of the same material as the laminate 100, is formed on the polished upper surface of the laminate 100 while exposing the connection terminals 103 to the outside environment through the openings in the ceramic paste 104 (FIGS. 3D and 3E).

The ceramic paste 104 may be formed by using screen printing.

Then, the surface electrode 105 is formed on the upper surface of the ceramic paste 104, and is electrically connected to the connection terminals 103 of the internal electrode circuit pattern (FIG. 3F).

After the surface electrode 105 is formed on an upper surface of the ceramic paste, the laminate 100 having the ceramic paste 104 and the surface electrode 105 is re-fired at a predetermined temperature to thereby manufacture the ceramic substrate (FIG. 3G).

FIGS. 4A through 4H are views illustrating a process of manufacturing a ceramic substrate according to another exemplary embodiment of the invention. As shown in FIG. 4A, dummy ceramic sheets used to prevent the surface influence caused by constraining layers 101 are laminated on an upper surface of a ceramic laminate 100 including the internal electrode to thereby form a dummy layer 102. Here, the dummy sheets are preferably formed of the same material as the ceramic laminate 100.

Then, in order to perform a non-shrinkage process, at least one constraining ceramic sheet is laminated on the upper surface of the dummy layer 102 and a lower surface of the laminate 100 to form the constraining layers 101 (FIG. 4B). The constraining sheets have the same characteristics as described above.

Then, the non-shrinkage process is performed so that the laminate 100 having the constraining layers 101 thereon is fired at a predetermined temperature, and the laminate 100 is allowed to shrink only in a thickness direction. Then, the constraining layers 101 are removed (FIGS. 4C and 4D).

The surface of the laminate 100 is smoothed by polishing, and the ceramic paste 104, formed of the same material as the laminate 100, is formed on the upper surface of the laminate 100 while exposing connection terminals 103 to the outside environment through openings in the ceramic paste 104. The ceramic paste 104 may be formed by using screen printing (FIGS. 4E and 4F).

Then, a surface electrode 105 is formed on an upper surface of the ceramic paste 104, and is electrically connected to the connection terminals 103. The ceramic paste 104 and the surface electrode 105 are re-fired at a predetermined temperature to thereby manufacture a ceramic substrate (FIGS. 4G and 4H).

That is, as the ceramic paste 104 and the surface electrode 105 are fired at the same time, the ceramic paste 104, formed of the same material as the ceramic laminate 100, is formed integrally with the laminate 100. As the ceramic paste 104 is crystallized, a good adhesion between the ceramic paste 104 and the surface electrode 105 is obtained.

As set forth above, according to exemplary embodiments of the invention, ceramic paste, formed of the same material as a ceramic laminate, is formed on the polished surface of the ceramic laminate after a primary firing process, a surface electrode is formed on an upper surface thereof, and a secondary firing process is performed, such that adhesion between the ceramic paste and the surface electrode can be increased.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing a non-shrinkage ceramic substrate by firing a ceramic laminate including an internal electrode circuit pattern, the method comprising:
laminating at least one constraining ceramic sheet on each of the upper and lower surfaces of the ceramic laminate to form constraining layers;
performing a primary firing process on the ceramic laminate having the constraining layers thereon;
polishing the surface of the ceramic laminate from which the constraining layers are removed;
forming ceramic paste on the polished surface of the ceramic laminate while connection terminals of the internal electrode circuit pattern are exposed to the outside environment through openings in the ceramic paste;
forming a surface electrode on the surface of the ceramic paste by patterning so that the surface electrode is electrically connected to the connection terminals; and
performing a secondary firing process so that the surface electrode adheres to the ceramic paste.

2. The method of claim 1, wherein the ceramic paste is formed of the same material as the ceramic laminate.

3. The method of claim 1, wherein the ceramic paste is formed by screen printing.

4. The method of claim 1, wherein the secondary firing is co-firing so that the ceramic paste and the ceramic laminate are integrally formed with each other.

5. A method of manufacturing a non-shrinkage ceramic substrate by firing a ceramic laminate including an internal electrode circuit pattern, the method comprising:
laminating a dummy ceramic sheet on an upper surface of the ceramic laminate to form a dummy layer;
forming at least one constraining ceramic sheet on an upper surface of the dummy layer and a lower surface of the ceramic laminate;
performing a primary firing process on the ceramic laminate against which the dummy layer and the constraining layers are compressed;
polishing the surface of the ceramic laminate from which the dummy layer and the constraining layers are removed;
forming ceramic paste on the polished surface of the ceramic laminate while connection terminals of the internal electrode circuit pattern are exposed to the outside environment through openings in the ceramic paste;
forming a surface electrode on the surface of the ceramic paste so that the surface electrode is electrically connected to the connection terminals; and
performing a secondary firing process so that the surface electrode adheres to the ceramic paste.

6. The method of claim 5, wherein the ceramic paste is formed of the same material as the ceramic laminate.

7. The method of claim 5, wherein the ceramic paste is formed by screen printing.

8. The method of claim 5, wherein the secondary firing is co-firing so that the ceramic paste and the ceramic laminate are integrally formed with each other.

9. A non-shrinkage ceramic substrate comprising:
a ceramic laminate having an internal electrode circuit pattern therein;
ceramic paste provided on the polished surface of the ceramic laminate after firing while connection terminals of the internal electrode circuit pattern are exposed to the outside environment through openings in the ceramic paste; and
a surface electrode provided on the upper surface of the ceramic paste so that a surface electrode is electrically connected to the connection terminals.

10. The non-shrinkage ceramic substrate of claim 9, wherein the ceramic paste is provided between the ceramic laminate and the surface electrode, and provided on a surface of the ceramic laminate while the connection terminals are exposed to the outside environment through openings in the ceramic paste, so that the surface electrode is electrically connected to the connection terminals of the internal electrode circuit pattern.
